(19) United States
(12) Patent Application Publication
(10) Pub. No.: US 2024/0290795 A1
(43) Pub. Date: Aug. 29, 2024

(54) DISPLAY PANEL AND DISPLAY DEVICE

(71) Applicants: WUHAN TIANMA MICROELECTRONICS CO., LTD., Wuhan (CN); WUHAN TIANMA MICROELECTRONICS CO., LTD. SHANGHAI BRANCH, Shanghai (CN)

(72) Inventor: Peng ZHANG, Shanghai (CN)

(73) Assignees: WUHAN TIANMA MICROELECTRONICS CO., LTD., Wuhan (CN); WUHAN TIANMA MICROELECTRONICS CO., LTD. SHANGHAI BRANCH, Shanghai (CN)

(21) Appl. No.: 18/655,349

(22) Filed: May 6, 2024

(30) Foreign Application Priority Data
Dec. 25, 2023 (CN) 202311799134.X

(51) Int. Cl. H01L 27/12

(52) U.S. Cl. CPC H01L 27/124

(57) ABSTRACT

A display panel and a display device are provided. Data transfer wires electrically connected to first multiplexers pass through an active area and are electrically connected to data pins arranged in a chip binding area. Therefore, an area occupied by the data transfer wires in the border area is reduced, a space for wiring in the border area can be vacated and the border area can be narrowed. This follows the trend towards increasingly narrow borders of display devices.

The present application claims the priority to Chinese Patent Application No. 202311799134.X, filed on Dec. 25, 2023 with the China National Intellectual Property Administration, which is incorporated herein by reference in its entirety.

### FIELD

The present disclosure relates to the field of display technology, and in particular to a display panel and a display device.

### BACKGROUND

As display technologies advance, users have increasingly high demands for screen ratios of display devices. There is a growing trend towards increasingly narrow borders of the display devices nowadays. The display device has an active area and an inactive area. In most of the existing display devices, the active area includes a curved edge at a side of a drive chip. Multiple multiplexers configured to selectively transmit a data signal are arranged along the curved edge of the active area. A large number of wires connecting the multiplexers and the drive chip are arranged in the inactive area, resulting in wide borders of the display devices, which is inconsistent with the trend towards increasingly narrow borders.

### SUMMARY

The present disclosure provides a display panel and a display device.

A display panel is provided. The display panel includes an active area and a border area. In a first direction, the border area includes a chip binding area arranged on a first side of the active area. Multiple data pins are arranged in the chip binding area. The active area includes at least a curved edge at the first side of the active area along a second direction. The first direction intersects with the second direction. First multiplexers among multiplexers are arranged along the curved edge of the active area. The first multiplexers are electrically connected to the data pins through data transfer wires. The data transfer wires pass through the active area.

A display device is further provided. The display device includes a display panel. The display panel includes an active area and a border area. In a first direction, the border area includes a chip binding area arranged on a first side of the active area. Multiple data pins are arranged in the chip binding area. The active area includes at least a curved edge at the first side of the active area along a second direction. The first direction intersects with the second direction. First multiplexers among multiplexers are arranged along the curved edge of the active area. The first multiplexers are electrically connected to the data pins through data transfer wires. The data transfer wires pass through the active area.

### BRIEF DESCRIPTION OF THE DRAWINGS

In order to more clearly describe the embodiments of the present disclosure, drawings to be used in the description of the embodiments are briefly described hereinafter. The drawings described hereinafter are merely used for illustrating the embodiments of the present disclosure.

FIG. 1 is a schematic structural diagram illustrating a display panel according to an embodiment of the present disclosure;

FIG. 2 is a schematic structural diagram illustrating another display panel according to an embodiment of the present disclosure;

FIG. 3 is a schematic structural diagram illustrating another display panel according to an embodiment of the present disclosure;

FIG. 4 is a schematic structural diagram illustrating another display panel according to an embodiment of the present disclosure;

FIG. 5 is a schematic structural diagram illustrating another display panel according to an embodiment of the present disclosure;

FIG. 6 is a schematic structural diagram illustrating another display panel according to an embodiment of the present disclosure;

FIG. 7 is a schematic structural diagram illustrating another display panel according to an embodiment of the present disclosure;

FIG. 8 is a schematic structural diagram illustrating another display panel according to an embodiment of the present disclosure;

FIG. 9 is a schematic structural diagram illustrating another display panel according to an embodiment of the present disclosure;

FIG. 10 is a schematic structural diagram illustrating another display panel according to an embodiment of the present disclosure;

FIG. 11 is a schematic structural diagram illustrating another display panel according to an embodiment of the present disclosure;

FIG. 12 is a schematic structural diagram illustrating another display panel according to an embodiment of the present disclosure;

FIG. 13 is a schematic structural diagram illustrating another display panel according to an embodiment of the present disclosure;

FIG. 14 is a schematic structural diagram illustrating another display panel according to an embodiment of the present disclosure;

FIG. 15 is a schematic structural diagram illustrating another display panel according to an embodiment of the present disclosure;

FIG. 16 is a schematic structural diagram illustrating another display panel according to an embodiment of the present disclosure;

FIG. 17 is a schematic structural diagram illustrating another display panel according to an embodiment of the present disclosure;

FIG. 18 is a schematic structural diagram illustrating another display panel according to an embodiment of the present disclosure; and

FIG. 19 is a schematic structural diagram illustrating a display device according to an embodiment of the present disclosure.

### DETAILED DESCRIPTION

The embodiments of the present disclosure are clearly and completely described hereinafter in conjunction with the drawings of the embodiments of the present disclosure. Apparently, the embodiments described in below are only some rather than all embodiments of the present disclosure.

Various modifications and variations to the present disclosure without departing from the spirit or scope of the present disclosure. Therefore, the present disclosure is intended to cover the modifications and variations of the present disclosure falling within the scope of the appended claims (the claimed embodiments) and equivalents thereof. It should be noted that the implementations provided in the embodiments of the present disclosure can be combined with each other in case of no conflict.

As described in the background, the display device has the active area and the inactive area. In most of the existing display devices, the active area includes a curved edge at a side of a drive chip. Multiple multiplexers configured to selectively transmit a data signal are arranged along the curved edge of the active area. A large number of wires connecting the multiplexers and the drive chip are arranged in the inactive area, resulting in wide borders of the display devices, which is inconsistent with the trend towards increasingly narrow borders.

In view of this, a display panel and a display device are provided according to the embodiments of the present disclosure, to effectively solve the problem. An area occupied by wires in the border area is reduced, a space for wiring in the border area can be vacated and the border area can be narrowed, which follows the trend towards increasingly narrow borders of the display devices.

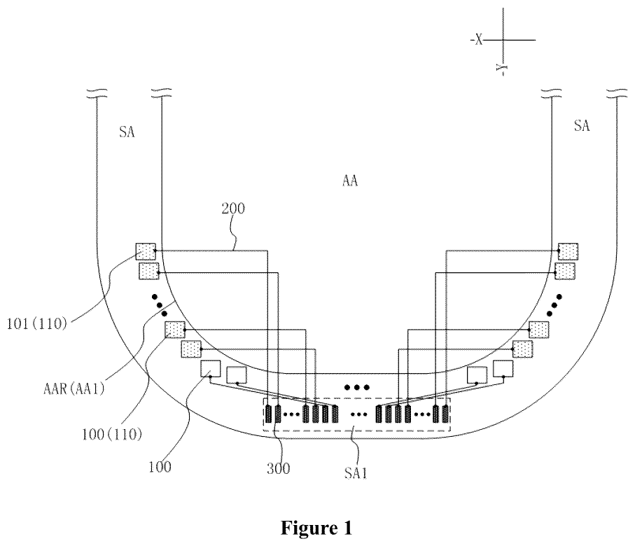

The embodiments of the present disclosure are described in detail in conjunction with FIG. 1 to FIG. 19.

Reference is made to FIG. 1, which is a schematic structural diagram illustrating a display panel according to an embodiment of the present disclosure. The display panel is divided into an active area AA and a border area SA. In a first direction Y, the border area SA includes a chip binding area SA1 arranged on a first side of the active area AA. Multiple data pins 300 are arranged in the chip binding area SA1. In a second direction X and on the first side of the active area AA, the active area AA includes at least a curved edge AA1. The first direction Y intersects with the second direction X.

Multiple multiplexers 100 are arranged between the active area AA and the chip binding area SA1. The multiple multiplexers 100 include multiple first multiplexers 110. The multiple first multiplexers 110 are arranged along the curved edge AA1 of the active area AA.

Multiple data transfer wires 200 each are provided with an end electrically connected to the first multiplexer 110 and another end electrically connected to the data pin 300. The multiple data transfer wires 200 pass through the active area AA.

In the embodiments of the present disclosure, an input terminal of the multiplexer is electrically connected to data transmission wiring, and multiple output terminals of the multiplexers are electrically connected to respective data cables. The data transmission wiring is configured to receive data signals outputted by the data pins, and transmit the data signals to the multiplexer. The multiplexer selectively outputs a data signal to pixels through a data wire connected to a selected output terminal. For example, an input terminal of the first multiplexer is electrically connected to the data transfer wire, and the multiple output terminals of the first multiplexer are connected to respective data cables. The multiplexer includes multiple switch transistors. First terminals of the multiple switch transistors are electrically connected to a data pin. Second terminals of the multiple switch transistors are connected to respective data cables. Control terminals of the multiple switch transistors are electrically connected to a controller. A data signal outputted by the data pin is inputted to the switch transistors. Then, the selected switch transistor is switched on under control of the controller. The data signal is transmitted to the data cable connected to the switch transistor, and thence to a corresponding pixel circuit. In the embodiments of the present disclosure, all switch transistors K are switched on similarly. In one embodiment, at least one of the switch transistors K is switched on differently. For example, the switch transistor K is an N-type switch transistor or a P-type switch transistor, which is not limited in the present disclosure.

It can be understood that in the embodiments of the present disclosure, the data transfer wires electrically connected to the first multiplexers pass through the active area and are electrically connected to the data pins arranged in the chip binding area. In this way, an area occupied by the data transfer wires in the border area is reduced, a space for wiring in the border area can be vacated and the border area can be narrowed, which follows the trend towards increasingly narrow borders of the display devices.

As illustrated in FIG. 1, the first multiplexers 110 according to the embodiments of the present disclosure are arranged in succession along the curved edge AA1 of the active area AA. That is, no other multiplexer 100 is arranged between adjacent first multiplexers 110. Therefore, it is unnecessary to arrange other data signal wire at a position, corresponding to the curved edge AA1 of the active area AA, in the border area SA. In this way, a space for wiring at the curved edge AA1 in the border area SA is vacated and the border area SA can be narrowed, which follows the trend towards the increasingly narrow borders of the display devices.

In an embodiment of the present disclosure, the active area is regular or is in an irregular shape provided with an R corner. For example, the active area is approximately a rectangle provided with four corners, and the four corners are all R corners. The R corner of the rectangular active area on a side of the chip binding area serves as the curved edge of the active area. As illustrated in FIG. 1, in the second direction X and on the first side of the active area AA, an edge of at least one side of the active area AA includes an R corner AAR. The R corner AAR serves as the curved edge AA1 of the active area AA. In an embodiment, at the R corner AAR, from a 1st multiplexer 101 arranged at the end of the multiple multiplexers 100, at least some of the multiple multiplexers 100 corresponding to the R corner AAR are the first multiplexers 110.

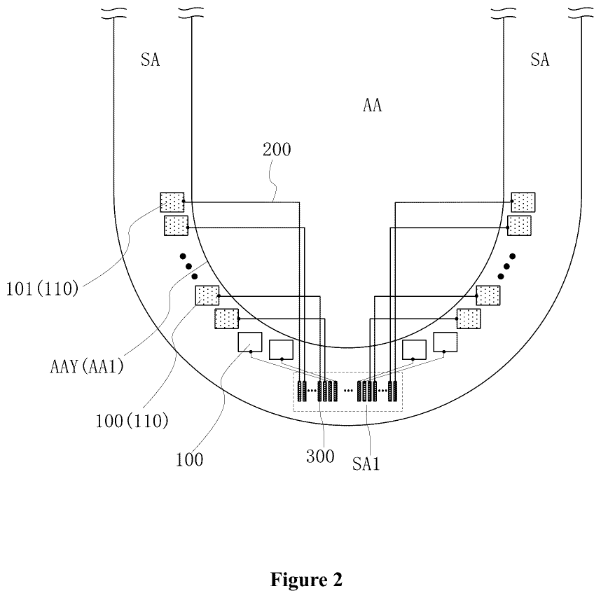

In an embodiment of the present disclosure, the active area is regular or is in an irregular shape including an arc. The arc serves as the curved edge of the active area. Reference is made to FIG. 2, which is a schematic structural diagram illustrating another display panel according to an embodiment of the present disclosure. In the second direction X and on the first side of the active area AA, an edge of at least one side of the active area AA is an arc AAY. The arc AAY serves as the curved edge AA1 of the active area AA. In an embodiment, at the circular arc AAY, from the 1st multiplexer 101 arranged at the end of the multiplexers 100, at least some of the multiplexers 100 corresponding to the circular arc are the first multiplexers 110.

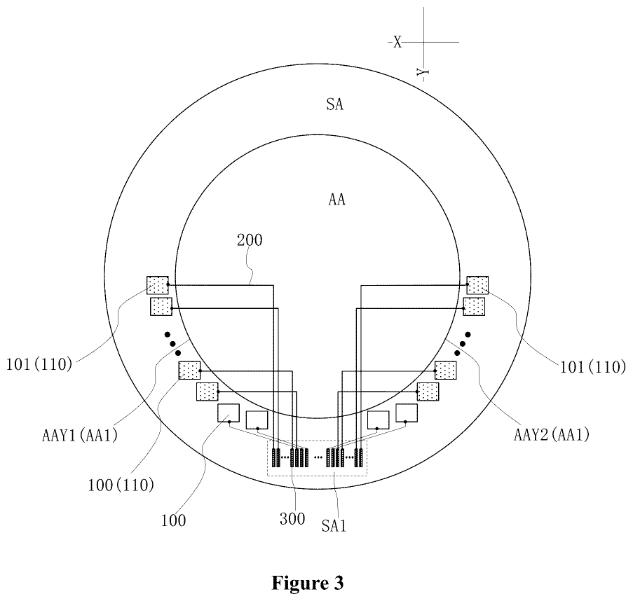

In an embodiment, reference is made to FIG. 3, which is a structural diagram illustrating another display panel according to an embodiment of the present disclosure. In the second direction X and on the first side of the active area AA, edges of two sides of the active area AA are the arcs defined as a first circular arc AAY1 and a second circular arc AAY2. The first circular arc AAY1 and the second circular arc AAY2 share the same endpoint. That is, the endpoint of the first circular arc AAY1 on the first side of the active area AA coincides with the endpoint of the second circular arc AAY2 on the first side of the active area AA. In an embodiment, at one of the first circular arc AAY1 and the second circular arc AAY2, from a 1st multiplexer 101 at the end of the multiple multiplexers 100, at most a half of the multiplexers 100 corresponding to the arc are the first multiplexers 110. In an embodiment, the active area AA according to the embodiments of the present disclosure is circular, which is not limited in the embodiments of the present disclosure.

It can be understood that the first circular arc and the second circular arc according to the embodiments of the present disclosure are directly connected to form a semicircle. Therefore, all multiplexers are arranged along arcs. By limiting the number of the first multiplexers arranged along the first circular arc and the second circular arc, the space for wiring at the arc edge in the border area is vacated, which follows the trend towards increasingly narrow borders of the display devices.

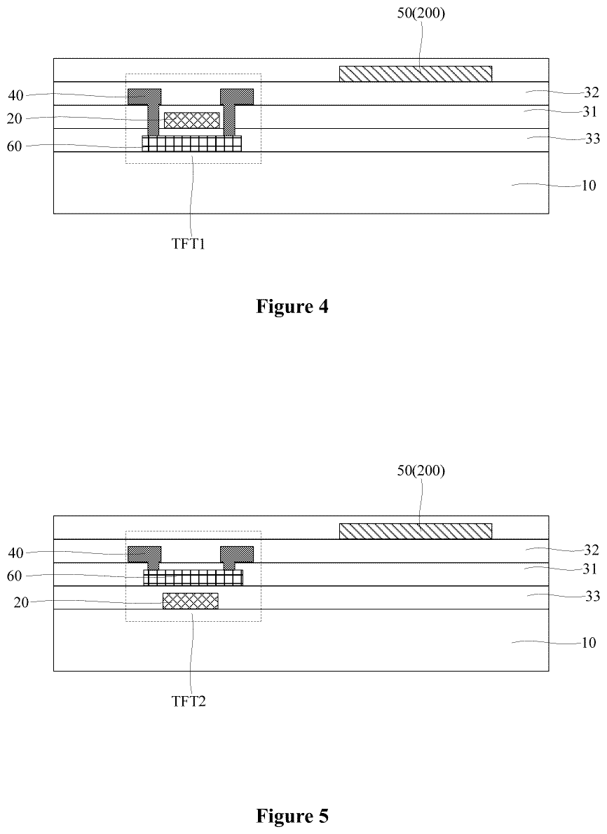

In an embodiment of the present disclosure, the data transfer wires are electrically connected to the first multiplexers in the border area, extend and pass through the active area, and then are electrically connected to the data pins in the border area. A part of the data transfer wire in the active area are arranged on the same conductive layer. In one embodiment, the part of the data transfer wire in the active area is divided into segments arranged on different conductive layers, and adjacent segments are electrically connected via a through hole. In addition, in the embodiments of the present disclosure, a part of the data transfer wire in the border area and the part of the data transfer wire in the active area are arranged on the same layer or in different layers, depending on practical applications. Reference is made to FIG. 4, which is schematic structural diagram illustrating another display panel according to an embodiment of the present disclosure. The display panel includes a substrate 10, a gate metal layer 20, a first insulation layer 31, a source drain metal layer 40, a second insulation layer 32, and a transfer metal layer 50. The gate metal layer 20 is arranged on a side of the substrate 10. The first insulation layer 31 is arranged on a side, of the gate metal layer 20, away from the substrate 10. The source drain metal layer 40 is arranged on a side, of the first insulation layer 31, away from the substrate 10. The second insulation layer 32 is arranged on a side, of the source drain metal layer 40, away from the substrate 10. The transfer metal layer 50 is arranged on a side of the second insulation layer 32, away from the substrate 10. The data transfer wire 200 is at least partially arranged in the gate metal layer 20, the source drain metal layer 40 or the transfer metal layer 50.

As illustrated in FIG. 4, the transistor in the circuit of the display panel according to the embodiments of the present disclosure is a top-gate transistor. A semiconductor layer 60 is arranged between the substrate 10 and the gate metal layer 20. A gate insulation layer 33 is arranged between the semiconductor layer 60 and the gate metal layer 20. The gate metal layer 20 includes a gate. The semiconductor layer 60 includes an active layer. The source drain metal layer 40 includes a source and a drain, and the source and drain are in contact with the active layer via a through hole. In this way, the gate, the active layer, the source and the drain form the top-gate transistor TFT1 in the circuit of the display panel.

Reference is made to FIG. 5, which is a schematic structural diagram illustrating another display panel according to an embodiment of the present disclosure. The transistor in the circuit of the display panel according to the embodiments of the present disclosure may be a bottom-gate transistor. A semiconductor layer 60 is arranged between the gate metal layer 20 and the first insulation layer 31. A gate insulation layer 33 is arranged between the semiconductor layer 60 and the gate metal layer 20. The gate metal layer 20 includes a gate. The semiconductor layer 60 includes an active layer. The source drain metal layer 40 includes a source and a drain, and the source and the drain are in contact with the active layer via a through hole. In this way, the gate, the active layer, the source and the drain form the bottom-gate transistor TFT2 in the circuit of the display panel.

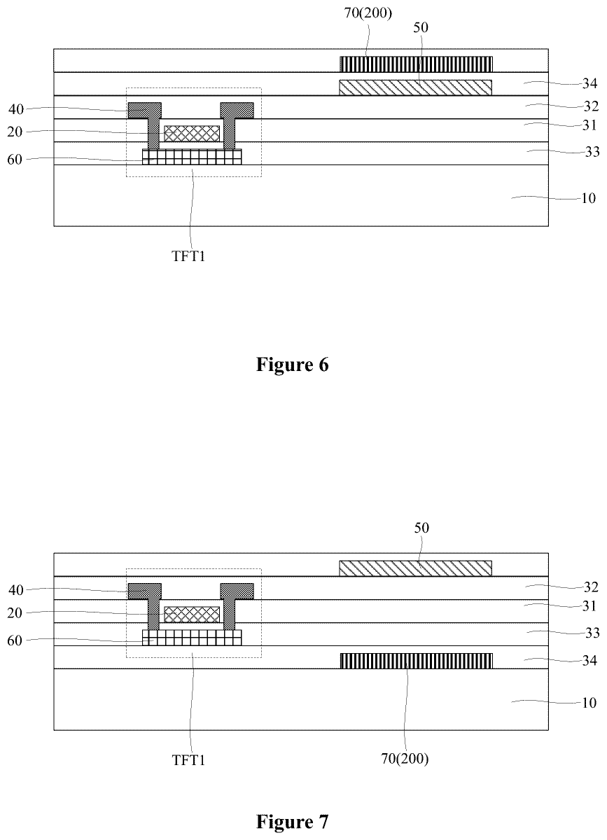

In order to arrange the data transfer wires and vacate space for wiring in other metal layers, the display panel according to the embodiments of the present disclosure includes more metal layers for arranging signal wires. Reference is made to FIG. 6, which is a schematic structural diagram illustrating another display panel according to an embodiment of the present disclosure. The display panel further includes an auxiliary insulation layer 34, and an auxiliary metal layer 70. The auxiliary insulation layer 34 is arranged on a side of the transfer metal layer 50 away from the substrate 10. The auxiliary metal layer 70 is arranged on a side of the auxiliary insulation layer 34 away from the substrate 10. The data transfer wire 200 is at least partially arranged in the gate metal layer 20, the source drain metal layer 40, the transfer metal layer 50 or the auxiliary metal layer 70.

The auxiliary metal layer according to the embodiments of the present disclosure may also be arranged between the gate metal layer and the substrate. Reference is made to FIG. 7, which is a schematic structural diagram illustrating another display panel according to an embodiment of the present disclosure. The display panel further includes an auxiliary insulation layer 34 and an auxiliary metal layer 70. The auxiliary insulation layer 34 is arranged between the gate metal layer 20 and the substrate 10. The auxiliary metal layer 70 is arranged between the auxiliary insulation layer 34 and the substrate 10. The data transfer wire 200 is at least partially arranged in the gate metal layer 20, the source drain metal layer 40, the transfer metal layer 50 or the auxiliary metal layer 70. In order to reduce coupling crosstalk between wires, the auxiliary insulation layer 34 according to the embodiments of the present disclosure is less than 3 in permittivity and is greater than 1 micrometers in thickness, to improve insulation performance of the auxiliary insulation layer 34 and reducing coupling of wires between the auxiliary metal layer 70 and other metal layers.

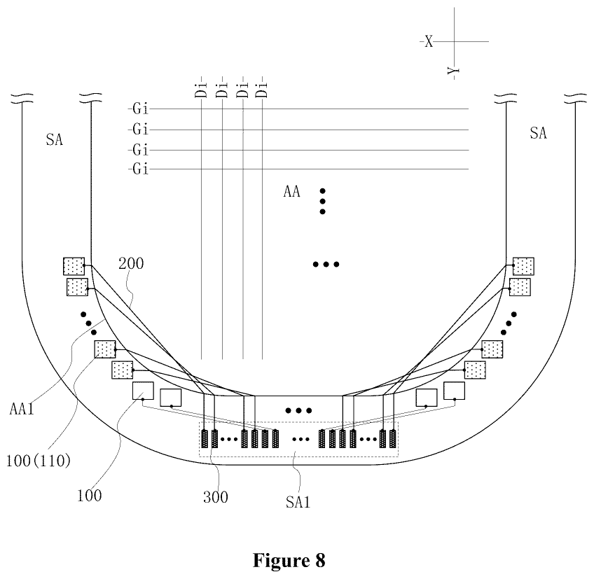

It can be understood that the data transfer wire according to the embodiments of the present disclosure may be completely arranged in a same conductive layer, or divided into multiple segments arranged in different conductive layers, depending on factors including a shape of the data transfer wire, the layout of the wires in the conductive layers, and the like. FIG. 8 is a schematic structural diagram illustrating another display panel according to an embodiment of the present disclosure. The part of the data transfer wire 200 in the active area AA extends as a straight line along a direction from the first multiplexer 110 to the data pin 300. The display panel according to the embodiments of the present disclosure includes gate wires Gi and data wires Di. The gate wires Gi are arranged long the first direction Y and extend along the second direction X, and the gate wires Gi are arranged in the gate metal layer. The data wires Di extend along the first direction Y and are arranged along the second direction X, and the data wires Di are arranged in the source drain metal layer. The first direction Y is perpendicular to the second direction X. In order to prevent the data transfer wire 200 extending in a straight line from intersecting with the gate wire Gi and the data wire Di in the same layer, the data transfer wire 200 is completely arranged in the transfer metal layer or the auxiliary metal layer. In addition, in order to prevent different data transfer wires 200 from intersecting with each other in the same layer, data transfer wires 200 that are likely to intersect with each other are arranged in different metal layers. The data transfer wire 200 is divided into a segment arranged in the transfer metal layer and another segment arranged in the auxiliary metal layer.

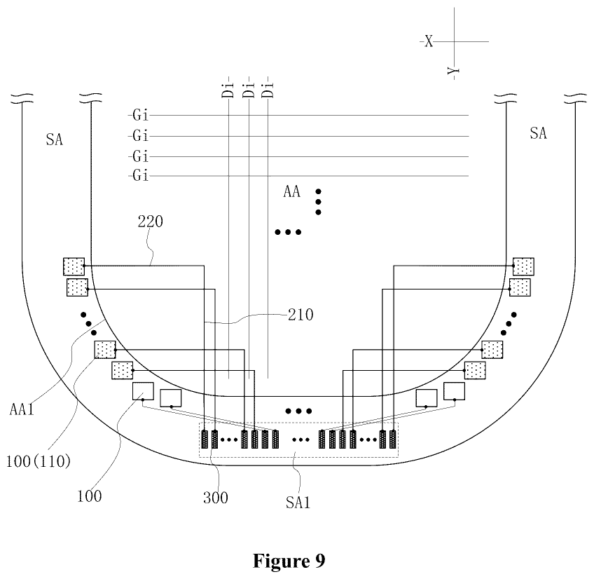

Reference is made to FIG. 9, which is a schematic structural diagram illustrating another display panel according to an embodiment of the present disclosure. The part of the data transfer wire 200 in the active area AA extends as a polyline including a first segment extending along the first direction Y and a second segment 220 extending along the second direction X. Similarly, the display panel according to the embodiments of the present disclosure includes gate wires Gi and data wires Di. The gate wires Gi are arranged along the first direction Y and extend along the second direction X, and the gate wires Gi are arranged in the gate metal layer. The data wires Di extend along the first direction Y and are arranged along the second direction Y, and the data wires Di are arranged in the source drain metal layer. The first direction Y is perpendicular to the second direction X. In order to prevent the data transfer wire 200 extending in a polyline from intersecting with the gate wire Gi and the data wire Di in a same layer, the first segment may be arranged in the source drain metal layer, the transfer metal layer or the auxiliary metal layer, and the second segment 220 may be arranged in the gate metal layer, the transfer metal layer or the auxiliary metal layer. In addition, in order to prevent different data transfer wires 200 from intersecting with each other in a same layer, the data transfer wires 200 that are likely to intersect with each other are arranged in different metal layers.

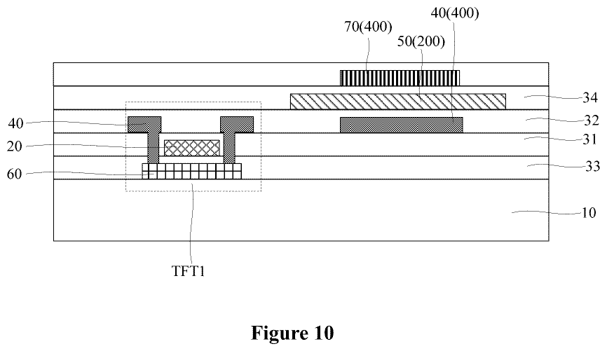

The data transfer wires according to the embodiments of the present disclosure pass through the active area in which a large number of wires are arranged. In order to reduce the impact of the wires in the active area on the data transfer wires, wiring is optimized in the embodiments of the present disclosure. Reference is made to FIG. 10, which is a schematic structural diagram illustrating another display panel according to an embodiment of the present disclosure. The display panel includes shielding wiring 400. The shielding wiring 400 is arranged in a layer different from the layer in which the data transfer wire 200 is arranged. In a direction perpendicular to a plane where the display panel is located, the data transfer wire 200 at least partially overlaps the shielding wiring 400. The data transfer wire 200 is resulted from the shielding wiring 400. In an embodiment, the data transfer wire 200 is partially arranged in the transfer metal layer 50, the auxiliary metal layer 70 is arranged on a side of the transfer metal layer 50 away from the substrate 10, the shielding wiring 400 includes a part arranged in the auxiliary metal layer 70 and/or another part arranged in the source drain metal layer 40. The shielding wiring 400 reduces coupling between some wires and the data transfer wire 200, improving signal transmission of the data transfer wire 200.

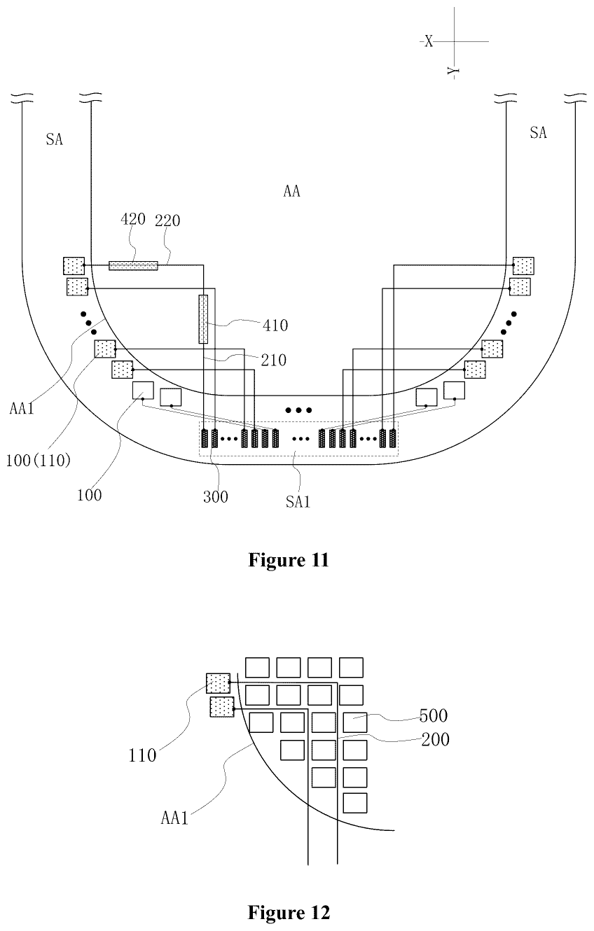

It should be noted that the above embodiments of the present disclosure are illustrated only by taking a case in which the data transfer wire is arranged in the transfer metal layer as an example. In a case that the data transfer wire is arranged on other metal layer, in the direction perpendicular to the plane where the display panel is located, the shielding wiring may be arranged in a metal layer above the data transfer wire and/or a metal layer under the data transfer wire. Regardless of the part of the data transfer wire in the active area extending as a straight line or a polyline, the shielding signal wires are arranged to reduce the coupling between the data transfer wire and other wires. FIG. 11 is a schematic structural diagram illustrating another display panel according to an embodiment of the present disclosure. In FIG. 12, only one data transfer wire 200 is illustrated. In the active area AA, the data transfer wire 200 is a polyline. The polyline data transfer wire 200 includes a first segment extending along the first direction Y and a second segment 220 extending along the second direction X. The shielding signal wiring 400 includes a first shielding signal wire 410 extending along the first direction Y and a second shielding signal wire 420 extending along the second direction X. In the direction perpendicular to the plane where the display panel is located, the first segment at least partially overlaps the first shielding signal wire 410 and is insulated from the first shielding signal wire 410, and/or the second segment 220 at least partially overlaps second shielding signal wire 420 and is insulated from the second shielding signal wire 420.

In an embodiment of the present disclosure, the shielding signal wiring is independently arranged in the display panel. In one embodiment, an existing wire in the display panel is reused to form the shielding signal wire, to make full use of the existing structure and reducing difficulty and production cost caused by arranging more wires. The shielding signal wire according to the embodiments of the present disclosure is a constant-voltage wire. The shielding signal wiring according to the embodiments of the present disclosure is source voltage wiring, reference voltage wiring, level signal wiring or grounded wiring, which is not limited in the embodiments of the present disclosure.

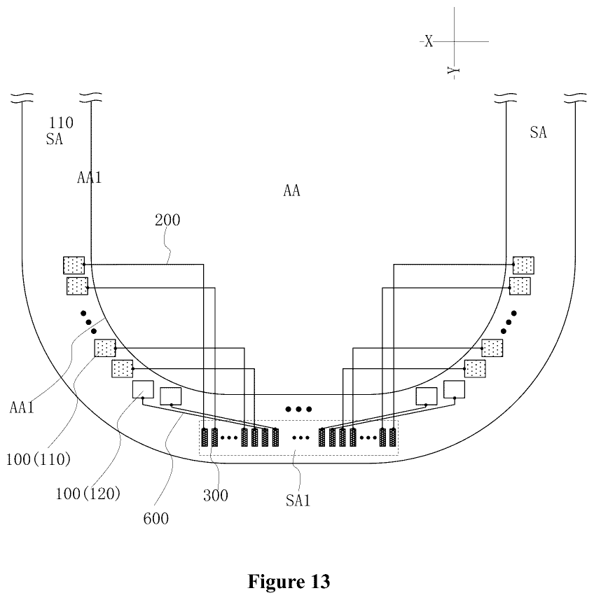

Reference is made to FIG. 12, which is a schematic structural diagram illustrating another display panel according to an embodiment of the present disclosure. FIG. 13 illustrates some of the wires arranged along the curved edge AA1. The active area according to the embodiments of the present disclosure includes multiple pixel circuits 500. In the active area AA, the data transfer wires 200 are arranged between adjacent pixel circuits 500. In a case that there is a circuit, arranged in a layer in which the data transfer wire 200 is arranged, among the pixel circuits 500, the data transfer wires 200 can be prevented from affecting the layout of the pixel circuits 500 by arranging the data transfer wires 200 between the pixel circuits 500. In a case that the pixel circuits 500 are completely arranged in a layer different from the layer in which the data transfer wire 200 is arranged, the data transfer wires 200 are arranged between the pixel circuits 500, and therefore no overlap between wiring results. That is, no coupling results, to improve signal transmission of the data transfer wires 200.

In an embodiment of the present disclosure, the multiplexer according to the embodiments of the present disclosure may further include other multiplexer in addition to the first multiplexer. In order to ensure the concordance of signals inputted to all multiplexers, the data transfer wire and other data transmission wiring for transmitting a data signal are optimized. Reference is made to FIG. 13, which is a schematic structural diagram illustrating another display panel according to an embodiment of the present disclosure. The multiple multiplexers 100 according to the embodiments of the present disclosure include multiple second multiplexers 120. Multiple data transmission wires 600 are arranged in the border area SA. An end of the data transmission wire 600 is electrically connected to the second multiplexer 120, and another end of the data transmission wire 600 is electrically connected to the data pin 300.

It can be understood that the first multiplexer and the second multiplexer according to the embodiments of the present disclosure each are configured to select a data cable and transmit a data signal to a corresponding pixel through the data cable. The data signal outputted by the data pin is inputted to the first multiplexer through the data transfer wire. The data signal outputted by the data pin is inputted to the second multiplexer through the data transmission wire. The first multiplexers among all multiplexers are arranged along the curved edge, of the border area, corresponding to the active area. Most of remaining multiplexers among all multiplexers are second multiplexers arranged in a region between the chip binding area and the active area. The data transfer wire passes through the active area, extends to the border area, and is electrically connected to the data pin. The data transmission wire is directly connected to the data pin in the border area. Therefore, the data transfer wire is generally longer than the data transmission wire.

In order to improve the concordance of signals transmitted in the data transfer wires and the data transmission wires, a difference, in impedance, between any two wires among all of the data transfer wires and the data transmission wires according to the embodiments of the present disclosure may be less than 0.1 Ohm, a difference between different data transfer wires in impedance, a difference between different data transmission wires in impedance, and a difference between the data transfer wire and the data transmission wire in impedance are small, which ensures the concordance of the signals transmitted to the first multiplexers and the second multiplexers, to improve the display effect of the display panel.

In addition, in the embodiments of the present disclosure, the data transfer wire passes through the active area and is connected to the data pin in the border area, while the data transmission wire is directly connected to the data pin in the border area, the data transfer wire is generally longer than the data transmission wire. In the embodiments of the present disclosure, the data transfer wire is at least partially wider than the data transmission wire, the data transfer wire matches the data transmission wire in impedance. Therefore, the signal transmitted through the data transfer wire is greatly consistent with the signal transmitted through the data transmission wire, to improve the display effect of the display panel.

In the embodiments of the present disclosure, widths of segments included in the signal wire are adapted to different signal wires in impedance. That is, a segment of the data transfer wire in the border area is at least partially wider than a segment of the data transfer wire in the active area, to reduce the impedance of the data transfer wire to match the impedance of the data transmission wire Therefore, the signal transmitted through the data transfer wire is greatly consistent with the signal transmitted through the data transmission wire, to improve the display effect of the display panel. In addition, the segment of the data transfer wire in the border area is widened to prevent the wiring in the active area from being affected by the adjustment to the width of the data transfer wire in the active area.

In the embodiments of the present disclosure, a thickness of the signal wire may be adjusted to ensure the concordance between different signal wires in impedance. That is, in the direction perpendicular to the plane where the display panel is arranged, a thickness of at least part of the data transfer wire is greater than a thickness of the data transmission wire, to reduce the impedance of the data transfer wire to match the impedance of the data transmission wire. Therefore, the signal transmitted through the data transfer wire is greatly consistent with the signal transmitted through the data transmission wire, to improve the display effect of the display panel.

In addition, in the embodiments of the present disclosure, a material of the signal wire may be adjusted to ensure the concordance between different signal wires in impedance. That is, an impedance of at least part of the data transfer wire is less than an impedance of the data transmission wire, to reduce the impedance of the data transfer wire to match the impedance of the data transmission wire Therefore, the signal transmitted through the data transfer wire is greatly consistent with the signal transmitted through the data transmission wire, to improve the display effect of the display panel.

It should be noted that in the embodiments of the present disclosure, in the adjustment to the parameter such as the width, the thickness, and the material of the data transfer wire, a type and a range of the parameter depend on practical applications and are not limited in the present disclosure.

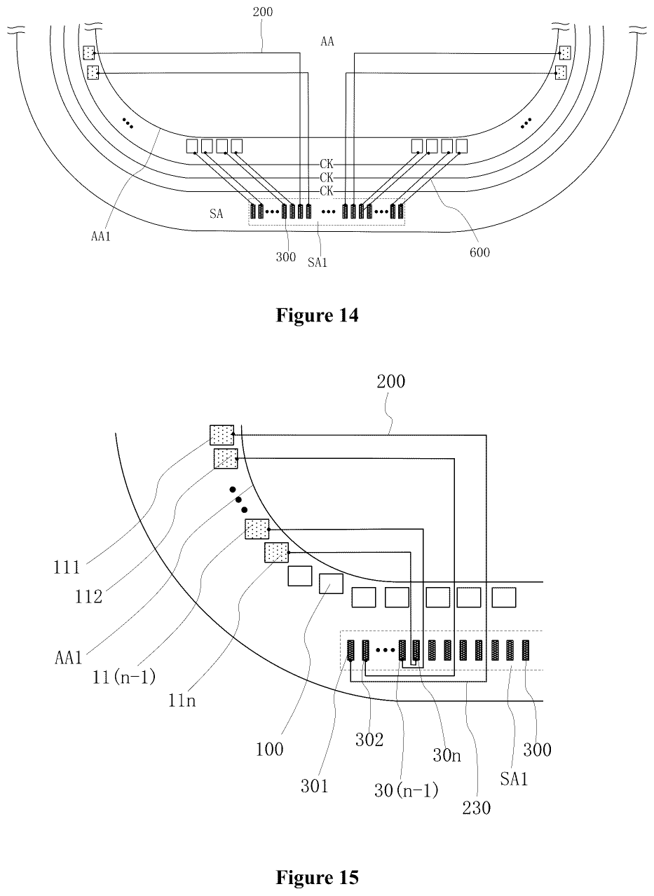

Reference is made to FIG. 14, which is a schematic structural diagram illustrating another display panel according to an embodiment of the present disclosure. Multiple margin signal wires CK extending along an edge of the active area AA are arranged in the border area SA. The margin signal wires CK extend and pass through the region between the multiplexers 100 and the data pins 300. At the curved edge AA1 in the direction perpendicular to the plane where the display panel is arranged, the data transfer wires 200 do not intersect with the margin signal wires CK. In other embodiments, between the multiplexers 100 and the data pins 300 in the direction perpendicular to the plane where the display panel is arranged, the data transmission wire 600 and the data transfer wire 200 each intersect with the margin signal wire CK. The data transmission wire 600 and the data transfer wire 200 each are insulated from the margin signal wire CK. That is, the data transmission wire 600 and the data transfer wire 200 intersect with one or more of the same margin signal wire CK.

It can be understood that the margin signal wire according to the embodiments of the present disclosure is a clock signal wire, a control signal wire, or the like. At the curved edge, the data transfer wires do not intersect with the margin signal wires, to avoid coupling between the margin signal wires and the data transfer wires. In the region between the multiplexers and the data pins, the data transmission wire and the data transfer wire are insulated from the same margin signal wire, the coupling between the data transmission wire and the margin signal wire is the same as the coupling between the data transfer wire and the margin signal wire. Therefore, the signal transmitted through the data transfer wire is greatly consistent with the signal transmitted through the data transmission wire, to improve the display effect of the display panel.

Reference is made to FIG. 15, which is a schematic structural diagram illustrating another display panel according to an embodiment of the present disclosure. At least some of the data transfer wires 200 each include a winding transfer wire 230 extending to a side of the data pin 300 away from the active area AA. On the side of the data pin 300 away from the active area AA, the winding transfer wire 230 is electrically connected to the data pin 300. In one embodiment, a path following which the data transfer wire 200 according to the embodiments of the present disclosure extends to the side away from the active area AA is arranged between adjacent data pins 300.

As illustrated in FIG. 15, in the embodiments of the present disclosure, the data pins 300 are arranged in an order consistent with an order in which the multiplexers 100 are arranged. For example, in the direction of line of sight, a 1st first multiplexer 111 to an N-th first multiplexer 11n are sequentially arranged from left to right, and N is an integer greater than 1. Similarly, a first data pin 301 to an N-th data pin 30n that correspond to the first multiplexers are sequentially arranged from left to right. In order to facilitate connecting the first multiplexers to the data pins in sequence, a data transfer wire 200 corresponding to at least one of the first multiplexers according to the embodiments of the present disclosure includes a winding transfer wire 230 extending to the side of the data pin 300 away from the active area AA, to electrically connect, in the region in which few wires are arranged, the first multiplexer to the data pin.

In an embodiment of the present disclosure, the data transfer wires 200 are electrically connected to the data pins 300 through the winding transfer wires 230 rather than connected, in the region, provide with a large number of wires, between the data pins 300 and the multiplexers 100, to the data pins 300, the wiring between the data pins 300 and the multiplexers 100 can be prevented from being affected by the connection between the data transfer wires 200 and the data pins 300. In addition, as illustrated in the comparison between FIG. 1 and FIG. 15, a distribution of different data transfer wires 200 in the active area AA can be optimized by electrically connecting the data transfer wires 200 to the data pins 300 through the winding data transfer wires 230, the different data transfer wires 200 do not intersect with each other, avoiding coupling and/or reducing difficulty in wiring between the data transfer wires 200.

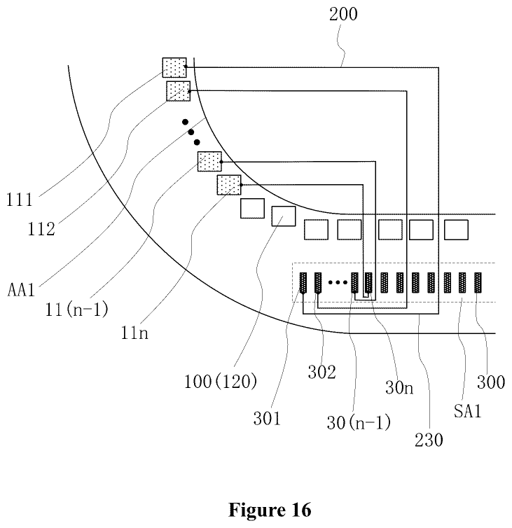

In an embodiment of the present disclosure, the data transfer wire passes through the opening between adjacent second multiplexers and extends to the chip binding area. Reference is made to FIG. 16, which is a schematic structural diagram illustrating another display panel according to an embodiment of the present disclosure. The multiple multiplexers 100 are sequentially arranged along an edge of a side of the active area AA toward the chip binding area SA. There are openings between adjacent second multiplexers among the second multiplexers 120. At least one of the data transfer wires 200 passes through the opening and is electrically connected to the data pin 300. In a case that the data transfer wire 200 according to the embodiments of the present disclosure includes a winding data transfer wire 230, a path following which the data transfer wire 200 extends passes through the gap between adjacent data pins 300.

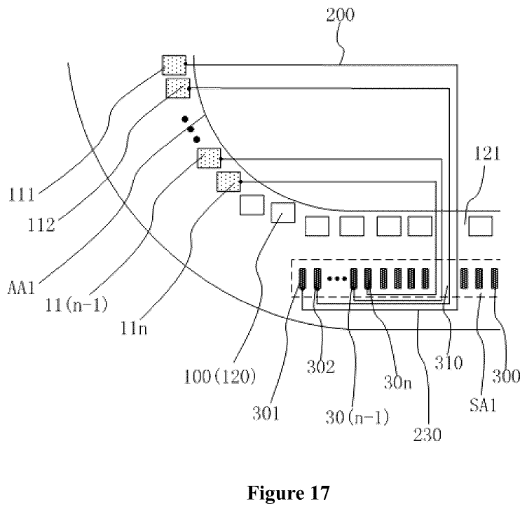

In some embodiments of the present disclosure, there is an opening between two adjacent second multiplexers among the multiple second multiplexers, and at least some of the data transfer wires pass through the opening and are electrically connected to the data pins. As illustrated in FIG. 17, the multiple multiplexers 100 according to the embodiments of the present disclosure are sequentially arranged along the edge of the active area AA toward the chip binding area SA, and there is an opening 121 between two adjacent second multiplexers among the multiple second multiplexers 120. Three or more (including all) of the data transfer wires 200 pass through the opening 121 and are electrically connected to the data pins 300. Similarly, in a case that the data transfer wire 200 in the embodiments of the present disclosure includes a winding transfer wire 230, there is an opening 310 between two adjacent data pins among the multiple data pins 300. At least some of the multiple data transfer lines 200 pass through the opening 310 and extend to sides, of the data pins 300, away from the active area AA.

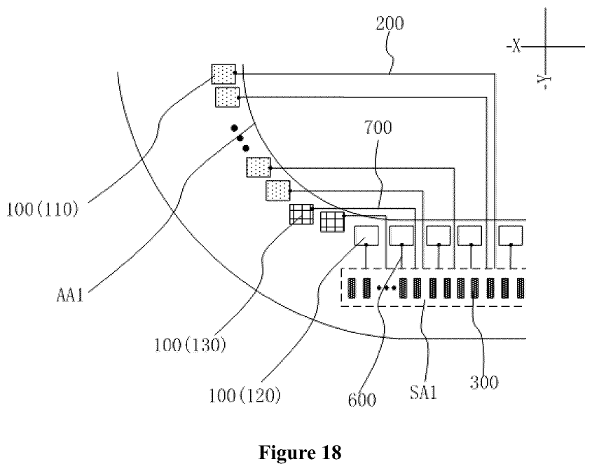

In an embodiment of the present disclosure, a data input wire through which a multiplexer close to the first multiplexers is connected to the data pin passes through the active area, the data transfer wire, the data transmission wire and the data input wire vertically extend along the first direction in a region between the data pins and the multiplexers and are connected to the data pins. Reference is made to FIG. 18, which is a schematic structural diagram illustrating another display panel according to an embodiment of the present disclosure. The multiple multiplexers 100 according to the embodiments of the present disclosure are sequentially arranged along an edge of a side, of the active area AA, toward the chip binding area SA. The multiple multiplexers 100 further include at least one third multiplexer 130, and the at least one third multiplexer 130 is arranged between the multiple first multiplexers 110 and the multiple second multiplexers 120. The display panel further includes at least one data input wire 700. An end of the data input wire 700 is electrically connected to the third multiplexer 130, the data input wire 700 passes through the active area AA, and another end of the data input wire 700 is electrically connected to the data pin 300.

In a region between the multiplexers 100 and the data pins 300, a segment of the data transfer wire 200, a segment of the data input wire 700 and a segment of the data transmission wire 600 are arranged vertically and extend along the first direction Y. The data pins are not connected to fan-out wires, facilitating formation of wiring.

It can be understood that in the embodiments of the present disclosure, the data transfer wires electrically connected to the first multiplexers pass through the active area, then extend to the border area and are electrically connected to the data pins, the data transfer wires can be arranged flexibly. A segment of the data transfer wire extending to the border area may extend along the first direction to form a vertical segment and is electrically connected to the data pin. The second multiplexers are arranged between the data pins and the active area. The second multiplexers may be arranged opposite to the data pins. The data transmission wires through which the data pins are connected to the second multiplexers are vertical segments extending along the first direction.

Furthermore, the third multiplexer among the multiple multiplexers is arranged between the first multiplexers and the second multiplexers. The third multiplexer does not correspond to the curved edge, or third multiplexer corresponds to the end of the curved edge, and therefore the third multiplexer cannot be classified as the first multiplexer. In addition, a wire through which the third multiplexer is connected to the data pin extends as an oblique line and intersects with the second direction, and therefore the third multiplexer cannot be classified as the second multiplexer. In view of this, the data input wire connected to the third multiplexer passes through the active area, then extends to the border area and is electrically connected to the data pin, to improve the flexibility for arranging the data input wire. Therefore, the segment of the data input wire extending to the border area extends along the first direction to form a vertical segment and is electrically connected to the data pin. In this way, between the multiplexers and the data pins, part of the data transfer wire, part of the data input wire, and part of the data transmission wire are vertical segments extending along the first direction, facilitating manufacturing wires and avoiding the problems such as breakage of wires caused by manufacturing of oblique wires.

A display device is further provided according to the embodiments of the present disclosure. The display device includes the display panel according to any one of the above embodiments.

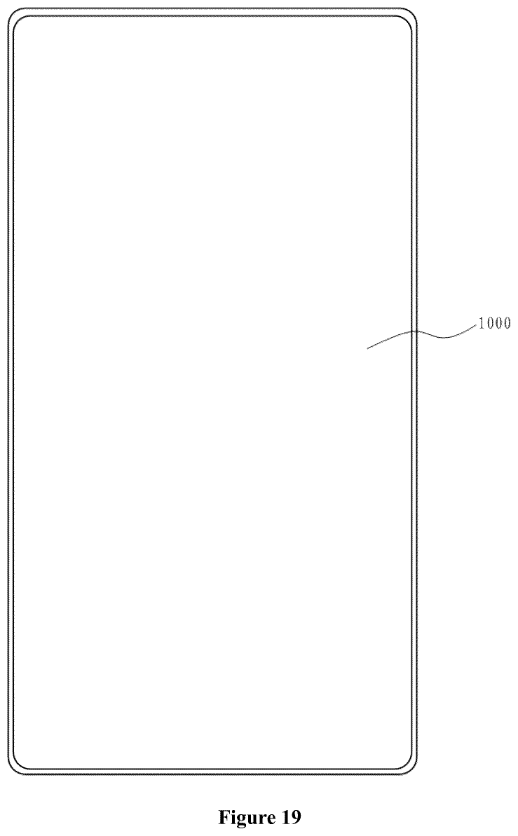

Reference is made to FIG. 19, which is a schematic structural diagram illustrating a display device according to an embodiment of the present disclosure. The display device 1000 according to the embodiments of the present disclosure may be a mobile terminal.

It should be noted that the display device according to the embodiments of the present disclosure may also be a laptop, a tablet computer, a computer, a wearable device, and the like, and the display device is not limited in the present disclosure.

A display panel and a display device are provided according to the embodiments of the present disclosure. The display panel includes an active area and a border area. In a first direction, the border area includes a chip binding area arranged on a first side of the active area. The multiple data pins are arranged in the chip binding area. In a second direction and on the first side of the active area, an edge of at least one side of the active area includes a curved edge. The first direction intersects with the second direction. The multiple multiplexers are arranged between the active area and the chip binding area. The multiple multiplexers include multiple first multiplexers. The multiple first multiplexers are arranged along the curved edge of the active area. The multiple data transfer wires each are provided with an end electrically connected to the first multiplexer and another end electrically connected to the data pin. The multiple data transfer wires pass through the active area.

It can be seen from the above that in the embodiments of the present disclosure, the data transfer wires electrically connected to the first multiplexers pass through the active area and are electrically connected to the data pins arranged in the chip binding area. Therefore, an area of a region, occupied by the data transfer wires, in the border area is reduced, a space for wiring in the border area can be vacated and the border area can be narrowed, which follows the trend towards increasingly narrow borders of the display devices.

In the description of the present disclosure, it should be understood that the orientation or positional relationships indicated by terms such as “center”, “longitudinal”, “lateral”, “length”, “width”, “thickness”, “up”, “down”, “forward”, “backward”, “left”, “right”, “vertical”, “horizontal”, “top”, “bottom”, “inner”, “outer”, “clockwise”, “anticlockwise”, “axial”, “radial”, and “circumferential” are based on the orientation or positional relationships illustrated in the drawings, and are merely for the convenience of description and the simplification of the description instead of indicating or implying that the device or component referred must be arranged in a particular orientation, or be constructed and operated in a particular orientation, and therefore should not be construed as a limitation to the scope of the present disclosure.

Furthermore, the terms “first” and “second” are merely for purpose of description, and should not be construed as indicating or implying relative importance or implying the number of the indicated features. Therefore, features defined with “first” or “second” may include at least one of the features explicitly or implicitly. In the description of the present disclosure, the term “multiple/plurality of” means at least two, such as two, or three, unless clearly defined otherwise.

In the present disclosure, unless clearly specified or defined otherwise, the terms such as “installation”, “connected with each other”, “connection”, and “fixation” should be understood in a broad sense. For example, “connection” may be a fixed connection, a detachable connection, or connection as an integral, may be a mechanical connection, an electrical connection, or connection in communication, may be a direct connection, an indirect connection via an intermediate medium, internal communication between two components, or interaction between two components, unless clearly defined otherwise.

In the present disclosure, unless clearly specified or defined otherwise, the first feature being “on” the second feature or “under” the second feature indicates that the first feature is directly in contact with the second feature or indirectly in contact with the second feature via an intermediate medium. Moreover, the first feature being “on”, “above” and “over” the second feature includes that the first feature is directly above and obliquely above the second feature, or simply indicates that the first feature is higher than the second feature in height with reference to a horizontal line. The first feature being “below”, “under” and “beneath” the second feature includes that the first feature is directly below and obliquely below the second feature, or simply indicates that the first feature is lower than the second feature in height with reference to a horizontal line.

Any reference in this specification to terms such as “an embodiment”, “some embodiments”, “example”, “specific embodiment”, or “some examples” means that a particular feature, structure, material or characteristic described in conjunction with the embodiment or example is included in at least one embodiment or example of the present disclosure. In this specification, the schematic expressions of the above terms are unnecessarily directed to a same embodiment or example. Moreover, the described feature, structure, material, or characteristics may be combined in a suitable manner in any one or more embodiments or examples.

Although the embodiments of the present disclosure are illustrated and described above, it can be understood that the above embodiments are exemplary and cannot be understood as a limitation to the present disclosure.

1. A display panel, comprising:
an active area; and
a border area, wherein
the border area comprises a chip binding area arranged on a first side of the active area in a first direction, and a plurality of data pins are arranged in the chip binding area;
the active area comprises at least a curved edge at the first side of the active area along a second direction, wherein the first direction intersects with the second direction;
first multiplexers among multiplexers are arranged along the curved edge of the active area; and
the first multiplexers are electrically connected to the data pins through data transfer wires, and the data transfer wires pass through the active area.

2. The display panel according to claim 1, wherein
the first multiplexers are arranged in succession along the curved edge of the active area.

3. The display panel according to claim 1, wherein
the active area comprises at least an R corner at the first side in the second direction, and the R corner is the curved edge of the active area; and
at least some of the multiplexers, from a 1st multiplexer at an end of the multiplexers at the R corner, are the first multiplexers.

4. The display panel according to claim 1, wherein
the active area comprises at least a circular arc at the first side in the second direction, and the circular arc is the curved edge of the active area; and
at least some of the multiplexers, from a 1st multiplexer at an end of the multiplexers at the circular arc, are the first multiplexers.

5. The display panel according to claim 4, wherein
the active area comprises at least a first circular arc and a second circular arc that are opposite at the first side in the second direction; and
the first circular arc and the second circular share an endpoint, and the first multiplexers accounts for a half of the multiplexers corresponding to one of the first circular arc and the second circular arc at most.

6. The display panel according to claim 5, wherein
the active area is circular.

7. The display panel according to claim 1, wherein
shielding wiring arranged in a layer different from a layer in which the data transfer wires are arranged; and
the data transfer wires partially intersect with the shielding wiring in a direction perpendicular to a plane where the display panel is arranged, and the data transfer wires are insulated from the shielding wiring.

8. The display panel according to claim 7, wherein
the data transfer wires each are a polyline comprising a first segment extending along the first direction and a second segment extending along the second direction;
the shielding wiring comprises a first shielding wire extending along the first direction and a second shielding wire extending along the second direction; and
the first segment at least partially overlaps the first shielding wire and is insulated from the first shielding wire, and/or, the second segment at least partially overlaps the second shielding wire and is insulated from the second shielding wire, in the direction perpendicular to the plane where the display panel is arranged.

9. The display panel according to claim 7, wherein the shielding wiring is constant-voltage wiring.

10. The display panel according to claim 9, wherein the shielding wiring is source voltage wiring, reference voltage wiring, level signal wiring or grounded wiring.

11. The display panel according to claim 1, wherein pixel circuits are arranged in the active area, and the data transfer wires are arranged between adjacent pixel circuits in the active area.

12. The display panel according to claim 1, wherein at least some of the data transfer wires each comprise a winding transfer wire extending to a side of the data pin away from the active area; and
the winding transfer wire is electrically connected to the data pin at the side of the data pin away from the active area.

13. The display panel according to claim 1, comprising:
a substrate;
a gate metal layer arranged on a side of the substrate;
a first insulation layer arranged on a side of the gate metal layer away from the substrate;
a source drain metal layer arranged on a side of the first insulation layer away from the substrate;
a second insulation layer arranged on a side of the source drain metal layer away from the substrate; and
a transfer metal layer arranged on a side of the second insulation layer away from the substrate, wherein the data transfer wires are at least partially arranged in the gate metal layer, the source drain metal layer or the transfer metal layer.

14. The display panel according to claim 13, further comprising:
an auxiliary insulation layer arranged on a side of the transfer metal layer away from the substrate, and an auxiliary metal layer arranged on a side of the auxiliary insulation layer away from the substrate; or
an auxiliary insulation layer arranged between the gate metal layer and the substrate, and an auxiliary metal layer arranged between the auxiliary insulation layer and the substrate, wherein the data transfer wires are at least partially arranged in the gate metal layer, the source drain metal layer, the transfer metal layer or the auxiliary metal layer.

15. The display panel according to claim 14, wherein
the auxiliary insulation layer is less than 3 in permittivity, and is greater than 1 micrometer in thickness.

16. The display panel according to claim 1, wherein
data transmission wires are arranged in the border area, and second multiplexers among the multiplexers are electrically connected to the data pins through the data transmission wires.

17. The display panel according to claim 16, wherein
an impedance difference between two wires among all the data transfer wires and all the data transmission wires is less than 0.1 Ohm.

18. The display panel according to claim 16, wherein the data transfer wires are at least partially wider than the data transmission wires.

19. The display panel according to claim 18, wherein
segments of the data transfer wires in the border area are at least partially wider than segments of the data transfer wires, in the active area.

20. The display panel according to claim 16, wherein
the data transfer wires are at least partially thicker than the data transmission wires in the direction perpendicular to a plane where the display panel is arranged.

21. The display panel according to claim 16, wherein
the data transfer wires are at least partially less than the data transmission wires in impedance.

22. The display panel according to claim 16, wherein
margin signal wires are arranged between the multiplexers and the data pins in the border area and extend along an edge of the active area;
the data transfer wires do not intersect with the margin signal wires at the curved edge in the direction perpendicular to a plane where the display panel is arranged; and/or
the data transmission wires and the data transfer wires interest with the margin signal wires between the multiplexers and the data pins, in the direction perpendicular to the plane where the display panel is arranged, and the data transmission wires and the data transfer wires are insulated from the margin signal wires.

23. The display panel according to claim 22, wherein
the margin signal wires each are a clock signal wire or a control signal wire.

24. The display panel according to claim 16, wherein
the multiplexers are sequentially arranged along an edge of the active area toward the chip binding area, and an opening is formed at the second multiplexers, wherein at least some of the data wires pass are electrically connected to the data pins through the opening.

25. The display panel according to claim 16, wherein
the multiplexers are sequentially arranged along an edge of the active area toward the chip binding area, and an opening is formed between two adjacent second multiplexers, wherein at least one of the data wires is electrically connected to the corresponding data pin through the opening.

26. The display panel according to claim 16, wherein
the multiplexers are sequentially arranged along an edge of the active area toward the chip binding area, at least one third multiplexer among the multiplexers are arranged between the first multiplexers and the second multiplexers;
the third multiplexer is electrically connected to the corresponding data pin through a data input wire, and the data input wire passes through the active area; and
wherein segments of the data transfer wires, a segment of the data input wire and segments of the data transmission wires extend along the first direction between the multiplexers and the data pins.

27. A display device, comprising: a display panel, wherein the display panel comprises:
an active area; and
a border area, wherein
the border area comprises a chip binding area arranged on a first side of the active area in a first direction, and a plurality of data pins are arranged in the chip binding area;
the active area comprises at least a curved edge at the first side of the active area along a second direction, wherein the first direction intersects with the second direction;
first multiplexers among multiplexers are arranged along the curved edge of the active area; and
the first multiplexers are electrically connected to the data pins through data transfer wires, and the data transfer wires pass through the active area.
